(19) United States
(12) Patent Application Publication
(10) Pub. No.: US 2026/0239499 A1
(43) Pub. Date: Aug. 13, 2026

(54) MICROWAVE-REACTIVE MICRO-HEATER, METHOD FOR DEVICE TRANSFER AND BONDING USING THE SAME, AND APPARATUS THEREFOR

(71) Applicant: ELECTRONICS AND TELECOMMUNICATIONS RESEARCH INSTITUTE, Daejeon (KR)

(72) Inventors: Jiho JOO, Daejeon (KR); Jungho SHIN, Daegu (KR); Chanmi LEE, Daejeon (KR); Gwang-Mun CHOI, Daejeon (KR); Yong Sung EOM, Daegu (KR); Kwang-Seong CHOI, Daejeon (KR); Jin Hyuk OH, Daegu (KR); Ki Seok JANG, Daejeon (KR)

(21) Appl. No.: 19/537,962

(22) Filed: Feb. 12, 2026

(30) Foreign Application Priority Data
Feb. 12, 2025 (KR) 10-2025-0018160
Dec. 3, 2025 (KR) 10-2025-0189877

(51) Int. Cl. H05B 6/80; H05B 1/02; H10H 29/01; H10H 29/03; H10W 72/00

(52) U.S. Cl. CPC H05B 6/80; H05B 1/0233; H10H 29/03; H10H 29/0364; H10W 72/07141; H10W 72/07235; H10W 72/073; H10W 72/07341

(57) ABSTRACT

A microwave-reactive micro-heater, fabricated from a material for generating heat in response to microwaves or electromagnetic waves, includes: an embossed structure formed on an upper surface of a planar substrate; a debossed structure formed within the embossed structure; and at least one of an adhesive material for temporarily fixing a device in the debossed structure and a through-hole for applying a vacuum.

### TECHNICAL FIELD

The present disclosure relates to a technology for transferring and bonding a device, and more particularly, to a microwave-reactive micro-heater, a device transfer and bonding method using the same, and an apparatus therefor, for enabling a single device or a plurality of devices to be transferred from a donor substrate and bonded to a target substrate using a microwave-reactive micro-heater.

### BACKGROUND

In general, technology related to device transfer and bonding methods is utilized in the process industry for small devices. The device may include a semiconductor device chiplet, an inorganic light-emitting diode (LED), and the like.

In recent years, electronic devices have become increasingly miniaturized and multifunctional. As one example, there is a chiplet package in which individual chiplets, each performing different functions, are integrated into a single package so as to operate as a single device with integrated functionality. In addition, there is a micro light-emitting diode (micro-LED) display in which an array of light-emitting diodes having sizes on the order of several micrometers to several tens of micrometers is arranged.

To fabricate such a device, a process of arranging a plurality of devices with high precision and bonding them to a substrate is performed. Various studies are being conducted to meet the demands for higher speed, precision, and yield in these transfer and bonding processes.

However, a conventional transfer and bonding technology processes only one device at a time, or even when processing a plurality of devices simultaneously, it is difficult to control the temperature of each device individually, resulting in a problem of non-uniform bonding quality. Furthermore, there is a problem of increased manufacturing cost due to a long time required for the bonding process and high energy consumption.

Therefore, there is a need for a technology capable of precisely transferring and bonding a plurality of micro-devices simultaneously, improving bonding quality by uniformly transferring heat to each device, and reducing process time and energy consumption.

The background technology of the present disclosure is disclosed in Korean Patent Application Publication No. 10-2013-0076725 (Published on Jul. 08, 2013).

### SUMMARY

According to one aspect, an object of the present disclosure is to provide a microwave-reactive micro-heater fabricated from a material capable of generating heat in response to microwaves or electromagnetic waves and including an embossed and debossed structure, a device transfer and bonding method using the same, and an apparatus therefor, to precisely transfer heat to a desired region.

According to another aspect, an object of the present disclosure is to provide a microwave-reactive micro-heater, a device transfer and bonding method using the same, and an apparatus therefor, which is capable of simultaneously transferring and bonding a plurality of micro-devices to reduce a manufacturing process time of electronic devices and improve a yield.

According to yet another aspect, an object of the present disclosure is to provide a microwave-reactive micro-heater, a device transfer and bonding method using the same, and an apparatus therefor, which is capable of reducing energy consumed in a bonding process and improving reliability of a bonded device by uniformly heating a heater using microwaves or electromagnetic waves.

In accordance with a first aspect of the present disclosure, there is provided a microwave-reactive micro-heater, fabricated from a material for generating heat in response to microwaves or electromagnetic waves, the microwave-reactive micro-heater including: an embossed structure formed on an upper surface of a planar substrate; a debossed structure formed within the embossed structure; and at least one of an adhesive material for temporarily fixing a device in the debossed structure and a through-hole for applying a vacuum.

Further, the material generating heat in response to the microwaves or the electromagnetic waves may include at least one selected from a group essentially consisting of silicon, ferrite, silicon carbide (SiC), zirconia, carbon nanotube, graphite, activated carbon, iron oxide, nickel, alumina, and conductive polymer.

Further, the embossed structure may have a shape of one of a rectangle, a circle, a triangle, and a cross, and the debossed structure has a shape the same as or different from the embossed structure.

Further, the adhesive material may include at least one selected from a group essentially consisting of rubber, acrylic adhesives, silicone adhesives, epoxy adhesives, polyimide adhesives, polyurethane adhesives, polyvinyl acetate (PVA), pressure-sensitive adhesives, and cyanoacrylate.

Further, the adhesive material may have a microwave-reactive material dispersed therein and generates heat in response to the microwaves or the electromagnetic waves.

Further, the microwave-reactive micro-heater may absorb at least one electromagnetic wave including at least one among microwaves, infrared, visible light, ultraviolet, and X-rays and converts the electromagnetic wave into heat.

Further, the electromagnetic waves may include a variable frequency microwave having a frequency changing continuously over a time axis.

Further, the electromagnetic waves may include a laser.

Further, the microwave-reactive micro-heater may be fabricated from a silicon wafer, and a doping concentration of the silicon wafer may be adjusted to control an efficiency of reacting to microwaves.

Further, the microwave-reactive micro-heater may include one or more embossed structures and one or more debossed structures, the one or more embossed structures may be formed on the upper surface of the planar substrate, the one or more debossed structures may be respectively formed within the one or more embossed structures, the microwave-reactive micro-heater may include an array of the embossed structure, the debossed structure, the one or more embossed structures and the one or more debossed structures arranged to simultaneously fix and transfer a plurality of devices at precise positions.

In accordance with a second aspect of the present disclosure, there is provided a device transfer and bonding method including: preparing a donor substrate on which a single device or a device array is arranged; aligning a microwave-reactive micro-heater over the donor substrate; lowering and pressing the aligned microwave-reactive micro-heater; picking up the device from the donor substrate to the microwave-reactive micro-heater by an adhesive force of an adhesive material or a vacuum suction force through a through-hole; aligning the microwave-reactive micro-heater, to which the device is temporarily bonded, over a target substrate; lowering and pressing the microwave-reactive micro-heater against a surface of the target substrate; generating microwaves or electromagnetic waves to heat the microwave-reactive micro-heater; bonding the device by an interconnection material between the device and the target substrate; and raising the microwave-reactive micro-heater to detach the microwave-reactive micro-heater from the device.

Further, the heating of the microwave-reactive micro-heater by generating microwaves or electromagnetic waves may use a combination of a plurality of wavelengths including at least one selected from the group consisting of the microwaves, variable frequency microwaves, and infrared lasers.

Further, the interconnection material may include at least one selected from the group consisting of a tin (Sn)-based solder, a tin-bismuth (SnBi) alloy solder, a tin-indium-bismuth (SnInBi) alloy solder, a gold-tin (AuSn)-based solder, an indium (In)-based solder, an anisotropic conductive paste (ACP), and an anisotropic conductive film (ACF).

Further, the microwave-reactive micro-heater may include a plurality of embossed and debossed structures, and simultaneously picks up a plurality of devices to simultaneously bond the plurality of devices to the target substrate.

Further, the detaching of the microwave-reactive micro-heater from the device may include reducing an adhesive force of the adhesive material or releasing a vacuum through the through-hole.

In accordance with a third aspect of the present disclosure, there is provided a device transfer and bonding apparatus including: a microwave-reactive micro-heater generating heat in response to microwaves or electromagnetic waves; a microwave generator generating the microwaves or the electromagnetic waves; a waveguide guiding the microwaves or the electromagnetic waves; a chamber confining the microwaves or the electromagnetic waves; a micro-heater fixing structure fixing the microwave-reactive micro-heater and applying pressure; and a stage fixing a donor substrate or a target substrate, wherein the micro-heater fixing structure and the stage are operable to move in x-y-z directions and a rotational direction to align the microwave-reactive micro-heater with a device.

Further, the chamber may be fabricated from a material reflecting the microwaves or the electromagnetic waves, and includes a metallic material.

Further, the micro-heater fixing structure may be composed of a material not reacting with the microwaves or the electromagnetic waves, and the material includes at least one selected from the group consisting of quartz, glass, Teflon, plastic, ceramic, intrinsic silicon, silicone, and siloxane.

Further, the chamber may be disposed at an upper portion and a lower portion of the microwave-reactive micro-heater, respectively, and irradiates the microwaves or the electromagnetic waves simultaneously from the upper portion and the lower portion of the microwave-reactive micro-heater.

Further, the microwave generator may be a laser generator, and may include: a homogenizer converting a laser beam generated from the laser generator into a uniform area light source; and an optical structure transmitting the area light source having passed through the homogenizer, the optical structure being composed of at least one of quartz, glass, and sapphire, wherein the area light source may pass through the optical structure and may be locally absorbed by a device or a plurality of devices to selectively heat the device, and may melt and cure an interconnection material between the device and a substrate to bond the device to the substrate.

According to one aspect, the present disclosure enables precise heat transfer to a desired region by using a micro-heater fabricated from a material reacting to microwaves or electromagnetic waves.

According to another aspect, the present disclosure enables a device to be precisely fixed and transferred using an adhesive material or a through-hole formed in a debossed structure of a micro-heater formed with an embossed and debossed structure.

According to yet another aspect, the present disclosure enables a reduction in manufacturing process time and energy for electronic devices by allowing a plurality of electronic devices to be bonded to a target substrate at once.

According to yet another aspect, the present disclosure enables ensuring uniformity of bonding quality and improving reliability of the device by uniformly heating a heater using microwaves or electromagnetic waves.

### BRIEF DESCRIPTION OF THE DRAWINGS

FIGS. 1A and 1B illustrate a schematic structure of a microwave-reactive micro-heater according to an embodiment of the present disclosure.

FIG. 2 illustrates a schematic structure of a microwave-reactive micro-heater according to another embodiment of the present disclosure.

FIGS. 3A and 3B illustrate a fabrication structure of a microwave-reactive micro-heater according to yet another embodiment of the present disclosure, and show dimensions for each component of a microwave-reactive micro-heater.

FIGS. 4A and 4B show a structure in which an adhesive material is disposed in a debossed region of a microwave-reactive micro-heater according to an embodiment of the present disclosure.

FIGS. 5A and 5B show a structure in which a through-hole is formed in a debossed region of a microwave-reactive micro-heater according to another embodiment of the present disclosure.

FIG. 6 is a flowchart illustrating a device transfer and bonding method using a microwave-reactive micro-heater according to an embodiment of the present disclosure.

FIGS. 7A to 7D illustrate steps of a device transfer and bonding method using a microwave-reactive micro-heater according to an embodiment of the present disclosure.

FIG. 8 is an exemplary view showing a device transfer and bonding method using electromagnetic waves according to another embodiment of the present disclosure.

FIG. 9 is an exemplary view showing a device transfer and bonding method using a micro-heater in which a microwave-reactive material is partially disposed according to yet another embodiment of the present disclosure.

FIG. 10 is an exemplary view illustrating a schematic structure of a transfer and bonding apparatus using a microwave-reactive micro-heater according to an embodiment of the present disclosure.

FIG. 11 is an exemplary view illustrating a schematic structure of a transfer and bonding apparatus using a microwave-reactive micro-heater according to another embodiment of the present disclosure.

### DETAILED DESCRIPTION

Hereinafter, an embodiment of the present disclosure will be described with reference to the accompanying drawings.

In this process, the thicknesses of lines shown in the drawings or the sizes of components may be exaggerated for clarity and convenience of explanation. In addition, the terms described below are defined in consideration of their functions in the present disclosure, and thus may vary depending on the intention or custom of a user or an operator. Accordingly, the definitions of such terms should be determined based on the overall contents of this specification.

Hereinafter, embodiments of the present disclosure will be described in detail with reference to the accompanying drawings so that a person having ordinary skill in the art to which the present disclosure pertains can readily practice the invention. However, the present disclosure can be embodied in various different forms and is not limited to the embodiments described herein. In addition, in order to clearly describe the present disclosure in the drawings, parts not related to the description are omitted, and throughout the specification, similar reference numerals are used to designate similar parts.

Throughout the specification, when a part is described as “including” a certain component, it means that the part may further include other components, rather than excluding other components, unless specifically stated otherwise.

The terms or words used in this specification and the claims should not be interpreted as being limited to their ordinary or dictionary meanings, but should be interpreted in accordance with the technical spirit of the present disclosure based on the principle that an inventor may appropriately define the concepts of terms in order to explain the invention in the best possible manner.

Accordingly, the embodiments described in the present specification and the configurations shown in the drawings are merely some of the most preferred embodiments of the present disclosure and do not represent all of the technical spirit of the present disclosure. Therefore, it should be understood that various equivalents and modifications capable of replacing these embodiments may exist at the time of filing of the present application. In addition, as used herein, the terms “comprise,” “include,” and/or “comprising,” “including” specify the presence of stated features, numbers, steps, operations, components, elements, and/or groups thereof, but do not preclude the presence or addition of one or more other features, numbers, steps, operations, components, elements, and/or groups thereof. Further, when describing embodiments of the present disclosure, the expressions “may” or “can” include one or more embodiments of the present disclosure.

In addition, for convenience of understanding the invention, the accompanying drawings may not be drawn to scale, and the dimensions of some components may be exaggerated. Also, the same reference numerals may be used to refer to the same components in different embodiments.

A statement that two objects are “identical” means that they are “substantially identical.” Accordingly, “substantially identical” may include cases in which a deviation regarded as low in the relevant art, for example, a deviation within 5%, is present. In addition, stating that a parameter is uniform within a predetermined region may mean that the parameter is uniform from an average perspective.

Although the terms “first,” “second,” and the like are used to describe various components, these components are not limited by such terms. These terms are used only to distinguish one component from another, and unless specifically stated otherwise, a first component may be a second component.

Throughout the specification, unless specifically stated otherwise, each component may be singular or plural.

When it is stated that an arbitrary component is disposed “on (or under)” or “above (or below)” a component, this may mean not only that the arbitrary component is disposed in contact with an upper surface (or lower surface) of the component, but also that another component may be interposed between the component and the arbitrary component disposed thereon (or thereunder).

In addition, when it is described that one component is “connected,” “coupled,” or “joined” to another component, it should be understood that the components may be directly connected or joined, or that another component may be interposed therebetween, or that the components may be connected, coupled, or joined through another component. Further, when a part is described as being electrically coupled to another part, this includes not only direct electrical coupling but also indirect electrical coupling with another element interposed therebetween.

Throughout the specification, the expression “A and/or B” means A, B, or both A and B, unless specifically stated otherwise. That is, “and/or” includes all combinations or any combination of the listed items. When the expression “C to D” is used, it means C or more and D or less, unless specifically stated otherwise.

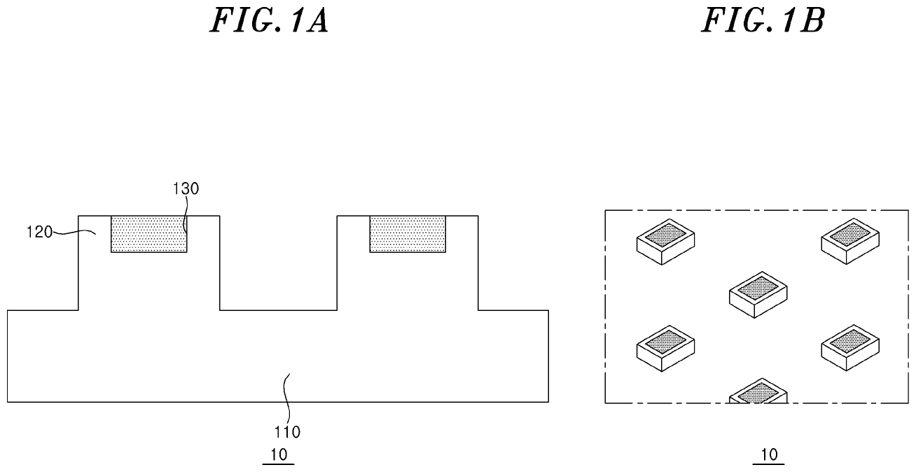

FIGS. 1A and 1B illustrate a schematic structure of a microwave-reactive micro-heater 10 according to an embodiment of the present disclosure.

Referring to FIG. 1A illustrates a cross-sectional structure of a microwave-reactive micro-heater 10, and FIG. 1B illustrates a perspective structure of the microwave-reactive micro-heater 10.

The microwave-reactive micro-heater 10 according to the present embodiment is fabricated from a material capable of generating heat in response to microwaves or electromagnetic waves. Microwave-reactive materials include silicon, ferrite, silicon carbide (SiC), zirconia, carbon nanotube (CNT), graphite, activated carbon, iron oxide, nickel, alumina, conductive polymer, water, salt, and the like, and materials in which these materials are mixed or combined, or materials including a portion thereof, also exhibit a characteristic of generating heat by absorbing microwaves or electromagnetic waves.

For these materials, the degree of reaction with microwaves and the amount of generated heat may vary depending on the arrangement and number of electrons constituting the material. Furthermore, a thermal conductivity characteristic of the material may be a characteristic determining how effectively heat may be transferred to a device in the structure of the micro-heater.

As illustrated in FIG. 1A, the microwave-reactive micro-heater 10 includes an embossed structure 120 formed on an upper surface of a planar substrate 110 and a debossed structure 130 formed within the embossed structure 120. A depth of the debossed structure 130 may be from 1.2 μm to 60 μm.

An adhesive material A may be disposed in the debossed structure 130. The adhesive material A serves to temporarily fix the device. For the adhesive material A, one or more selected from the group consisting of rubber, acrylic adhesives, silicone adhesives, epoxy adhesives, polyimide adhesives, polyurethane adhesives, polyvinyl acetate (PVA), pressure-sensitive adhesives (PSA), and cyanoacrylate may be used alone or in combination, and may also be used in the form of other adhesive materials including these components.

As illustrated in FIG. 1B, the microwave-reactive micro-heater 10 may be fabricated in a form in which a plurality of embossed structures 120 and debossed structures 130 are arranged. Through this arrangement structure, a plurality of devices may be simultaneously fixed at precise positions and transferred.

The microwave-reactive micro-heater 10 may absorb microwaves and convert the microwaves into heat. Here, the microwaves may include electromagnetic waves with a wavelength of 1 mm to 1 m. Furthermore, the microwave-reactive micro-heater 10 may absorb not only microwaves but also electromagnetic waves in the regions of infrared (wavelength 700 nm to 1 mm), visible light (wavelength 400 nm to 700 nm), ultraviolet (wavelength 10 nm to 400 nm), and X-rays (wavelength 10 pm to 10 nm) and convert them into heat.

The electromagnetic wave may not have a single wavelength. In one embodiment, the electromagnetic wave may be a variable frequency microwave (VFM) having a frequency changing continuously over the time axis. The electromagnetic wave may include a laser. In another embodiment, the electromagnetic wave may be a combination of a plurality of wavelengths, such as a combination of microwaves and infrared rays from different frequency regions.

When the microwave-reactive micro-heater 10 absorbs electromagnetic waves and converts them into heat, a conversion efficiency may vary depending on characteristics of the material. Therefore, a conversion rate of converting microwaves into heat by absorption may be controlled through the single and combined use of microwave-absorbing materials. By controlling the heat conversion rate of microwaves, it is possible to control the maximum temperature, the rate of temperature increase, the microwave energy, and the like, and to maximize the heat conversion efficiency of microwaves. Accordingly, the energy used in the bonding process may be reduced.

According to one embodiment, for a silicon wafer, a degree of efficiency of reacting to microwaves may be controlled by adjusting a doping concentration. Therefore, it may be suitable for precise temperature control including the temperature increase rate of the micro-heater. For example, a silicon wafer doped at a high concentration may have a faster rate at which a temperature increases in response to microwaves compared to a silicon wafer with a low doping concentration.

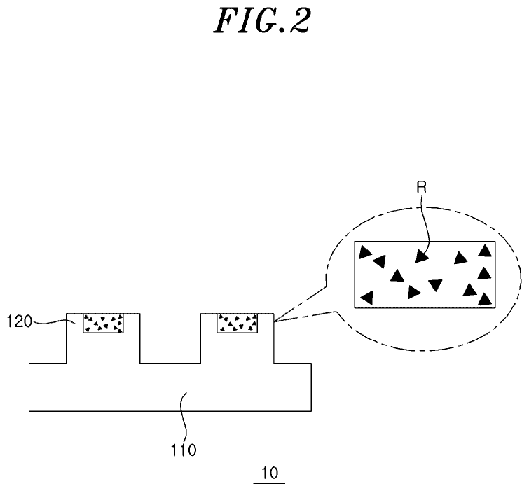

FIG. 2 is an exemplary view illustrating a schematic structure of a microwave-reactive micro-heater 10 according to another embodiment of the present disclosure.

Referring to FIG. 2, the microwave-reactive micro-heater 10 according to the embodiment includes a structure in which a microwave-reactive material R is dispersed within an adhesive material A, allowing the adhesive material A itself to generate heat.

The structure illustrated in FIG. 2 is characterized by the adhesive material A disposed in the debossed structure 130 reacting to microwaves to directly generate heat, unlike the structure illustrated in FIG. 1. The microwave-reactive material R dispersed within the adhesive material A may include Silicon, Ferrite, Silicon Carbide, Zirconia, Carbon Nanotube, Graphite, Activated Carbon, Iron Oxide, Nickel, Alumina, Conductive polymer, and the like.

At this time, the structure, excluding the adhesive material A, may be formed of a microwave-reactive material or a microwave-non-reactive material. The microwave-non-reactive material may include materials such as quartz, glass, Teflon, plastic, ceramic, intrinsic silicon (undoped), silicone, and siloxane.

When the microwave-reactive material is dispersed within the adhesive material A, upon irradiation of microwaves, the reactive material dispersed within the adhesive material A may directly generate heat, causing a temperature of the adhesive material A in contact with the device to increase. This structure may have an improved energy efficiency because a heat transfer path is shorter than heating the entire heater structure.

Furthermore, the amount and distribution of heat generation may be controlled by adjusting a concentration, size, and distribution of the microwave-reactive material R within the adhesive material A. For example, a higher concentration of the microwave-reactive material R may generate more heat, and a smaller size of the microwave-reactive material R may be more uniformly dispersed within the adhesive material A to achieve a uniform thermal distribution.

In one embodiment, when the structure itself is composed of a microwave-non-reactive material and the microwave-reactive material R is dispersed only within the adhesive material A, the structure is not heated, and only the adhesive material A may be selectively heated. Such a structure reduces unnecessary heat loss and allows for precise control of the adhesive force between the adhesive material A and the device.

In another embodiment, when the structure itself is also composed of the microwave-reactive material R and the microwave-reactive material R is also dispersed within the adhesive material A, the structure and the adhesive material A are heated simultaneously, thereby achieving a faster temperature increase.

As illustrated in FIG. 2, the microwave-reactive micro-heater 10 in which the microwave-reactive material R is dispersed within the adhesive material A includes a structure in which the adhesive material A is disposed in the debossed structure 130, and this adhesive material A may simultaneously perform the function of temporarily fixing the device and the function of generating heat in response to microwaves.

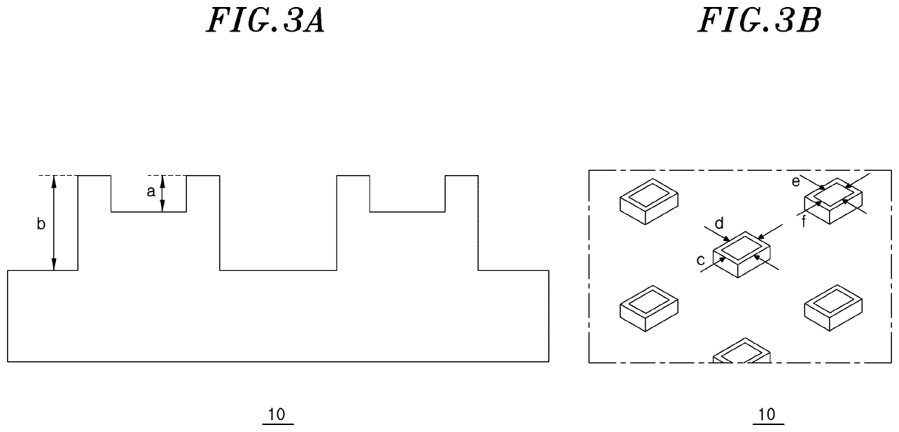

FIG. 3 is an exemplary view illustrating a fabrication structure of a microwave-reactive micro-heater 10 according to yet another embodiment of the present disclosure.

Referring to FIG. 3A illustrates a cross-sectional structure of a microwave-reactive micro-heater 10, and FIG. 3B illustrates a perspective structure of the microwave-reactive micro-heater 10.

The microwave-reactive micro-heater 10 according to the embodiment is fabricated from a material capable of generating heat in response to microwaves or electromagnetic waves, similar to the microwave-reactive micro-heater 10 shown in FIG. 1. The material of the micro-heater may be a silicon wafer.

As illustrated in FIG. 3A, the microwave-reactive micro-heater 10 includes an embossed structure 120 formed on an upper surface of a planar substrate 110 and a debossed structure 130 formed within the embossed structure 120. FIG. 3 specifies a depth of the debossed structure 130, and this depth may be determined by a thickness of the device to be transferred and bonded.

An adhesive material A may be disposed in the debossed structure 130, and the adhesive material A serves to temporarily fix the device. The depth of the debossed structure 130 may be designed by taking into account factors such as the thickness of the device, a thickness of the adhesive material A, and a roughness of a surface of the target substrate. For example, the thicker the device, the deeper the debossed structure 130 may be formed, thereby allowing the device to be stably positioned within the debossed structure 130.

As illustrated in FIG. 3B, the microwave-reactive micro-heater 10 may be fabricated in a form where a plurality of embossed structures 120 and debossed structures 130 are regularly arranged. Through this arrangement structure, a plurality of devices may be simultaneously fixed at precise positions and transferred. A spacing between the embossed structures 120 may be designed to correspond to a pitch between the devices.

An embossed pattern of the microwave-reactive micro-heater 10 is not limited to a rectangular shape. In one embodiment, the embossed pattern may include a circular, triangular, or cross shape, and may have various other shapes. Furthermore, a debossed pattern may be different from the shape of the embossed pattern. In one embodiment, the debossed pattern may include a circular, triangular, or cross shape, and may have various other shapes, and is not limited to only within the embossed pattern.

The microwave-reactive micro-heater 10 according to the embodiment may be fabricated using semiconductor manufacturing process technology with a microwave-reactive material such as a silicon wafer. In one embodiment, the embossed structures 120 and the debossed structures 130 may be formed using a photolithography process and an etching process. By using such a semiconductor manufacturing process, a large number of precise structures at the micrometer level may be fabricated.

In one embodiment, a microwave-reactive micro-heater 10 may be fabricated using a 300-millimeter silicon wafer. The 300-millimeter silicon wafer may be uniformly heated by microwaves. Therefore, a plurality of electronic devices fixed to the micro-heater may be bonded to the target substrate at once. This may reduce the time and energy required for the manufacturing process of electronic products.

FIGS. 3A and 3B illustratively show exemplary dimensions of respective components of the microwave-reactive micro-heater 10 according to the embodiment of the present disclosure.

Referring to FIG. 3A indicates each dimension in a cross-sectional structure of the microwave-reactive micro-heater 10, and FIG. 3B indicates each dimension in a perspective structure of the microwave-reactive micro-heater 10.

In the microwave-reactive micro-heater 10 according to the embodiment a dimension of each of the embossed structure 120 and the debossed structure 130 may be determined by a size of the device to be transferred and bonded.

As illustrated in FIG. 3A, dimensions by structure of the microwave-reactive micro-heater 10 may be indicated by ‘a’ and ‘b’. Dimension ‘a’ indicates the depth of the debossed structure 130 and is related to the thickness of the device. For example, the thicker the device, the deeper the depth ‘a’ of the debossed structure 130 may be formed. Dimension ‘b’ indicates a height of the embossed structure 120 and is related to the roughness of the surface of the target substrate, a height variation of the structure, a thickness of the interconnection material used, and the like.

Depending on experimental conditions, the dimension ‘b’ may be related to other physical variables. For example, the dimension ‘b’ may be determined according to a magnitude of pressure applied in a bonding process, an electrode arrangement structure between the device and the substrate, and the like. Each dimension may all include zero. That is, it may be a planar form without an embossed structure or a form without a debossed structure.

As illustrated in FIG. 3B, in the perspective structure of the microwave-reactive micro-heater 10, dimensions may be indicated by c, d, e, and f. Dimensions ‘c’ and ‘d’ are related to the pitch of the devices. For example, the narrower the spacing between devices, the smaller the dimensions ‘c’ and ‘d’ may be designed. Dimensions ‘e’ and ‘f’ are related to a length or area of the device. For example, the larger the size of the device, the larger the dimensions ‘e’ and ‘f’ may be designed.

Each dimension of the microwave-reactive micro-heater 10 may be variously designed according to a type, size, and arrangement form of the device to be transferred and bonded. For example, when transferring and bonding micro light-emitting diodes, since the size of the device is from several micrometers to tens of micrometers, each dimension of the micro-heater may also be precisely fabricated at the micrometer level correspondingly. Conversely, when transferring and bonding a millimeter-level device such as a semiconductor chiplet, each dimension of the micro-heater may also be fabricated at the millimeter level.

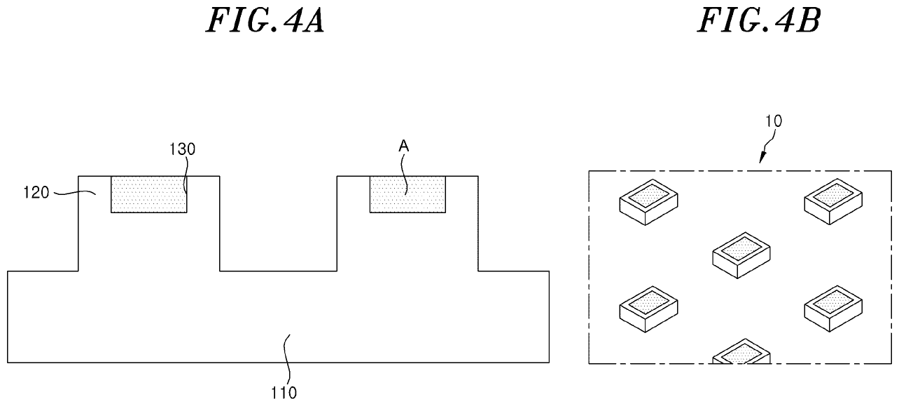

FIGS. 4A and 4B are exemplary views in which an adhesive material is disposed in the debossed structure of the microwave-reactive micro-heater according to the embodiment of the present disclosure.

Referring to FIG. 4A is a cross-sectional view illustrating the adhesive material disposed in the debossed structure of the microwave-reactive micro-heater, and FIG. 4B is a perspective view illustrating the adhesive material disposed in the debossed structure of the microwave-reactive micro-heater.

The microwave-reactive micro-heater 10 according to the embodiment may include the adhesive material A in the debossed structure, similar to the microwave-reactive micro-heaters 10 shown in FIGS. 1 to 3.

As illustrated in FIG. 4A, the adhesive material A is disposed in the debossed structure 130. The adhesive material A serves to temporarily fix the device. For the adhesive material A, one or more selected from the group consisting of rubber, acrylic adhesives, silicone adhesives, epoxy adhesives, polyimide adhesives, polyurethane adhesives, polyvinyl acetate (PVA), pressure-sensitive adhesive (PSA), and cyanoacrylate may be used alone or in combination, and may also be used in the form of other adhesive materials including these components.

The adhesive material A may fix a single or a plurality of devices on the micro-heater at precise positions. During a device pick-up process, when the micro-heater is pressed against a donor substrate, the adhesive material A comes into contact with the device, and the device is fixed to the micro-heater by an adhesive force of the adhesive material A. At this time, the adhesive force of the adhesive material A is greater than an adhesive force between the donor substrate and the device for the device to be picked up by the micro-heater.

The adhesive force of the adhesive material A may be controlled by the material, thickness, temperature, etc., of the adhesive material A. For example, heating the adhesive material A may increase the adhesive force, and cooling it may decrease the adhesive force. By using this characteristic, the adhesive force of the adhesive material A is increased when picking up the device, and after bonding the device to the substrate, the adhesive force of the adhesive material A is decreased to detach the micro-heater 10 from the device.

As illustrated in FIG. 4B, the adhesive material A is disposed in each of a plurality of debossed structures 130, so that a plurality of devices may be simultaneously fixed at precise positions. The adhesive material A disposed in the debossed structure 130 may be disposed at a height equal to or lower than the depth of the debossed structure 130. For example, when the adhesive material A completely fills the debossed structure 130, the device may be located at the same height as a surface of the micro-heater 10, and when the adhesive material A partially fills the debossed structure 130, the device may be located inside the debossed structure 130.

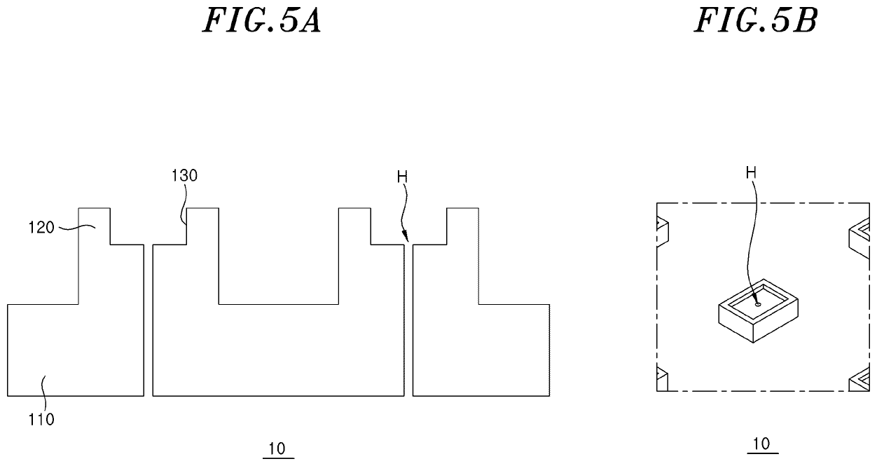

FIG. 5 is an exemplary view showing a structure in which a through-hole is formed in the debossed structure of the microwave-reactive micro-heater according to another embodiment of the present disclosure.

Referring to FIGS. 5A and 5B, FIG. 5A illustrates a cross-sectional view illustrating a through-hole formed in the debossed structure of the microwave-reactive micro-heater 10, and FIG. 5B is an enlarged perspective view illustrating debossed structure in which the through-hole is formed.

The microwave-reactive micro-heater 10 according to the embodiment may include a through-hole in the debossed structure 130, unlike the microwave-reactive micro-heaters 10 shown in FIGS. 1 to 4.

As illustrated in FIG. 5A, a through-hole H may be formed in the debossed structure 130, and a vacuum may be applied through the through-hole H. The through-hole H is formed to pass through from a bottom surface of the debossed structure 130 to a rear surface of the micro-heater 10. When a vacuum is applied through the through-hole H, the device is fixed by a vacuum suction force within the debossed structure 130.

The through-hole H may fix a single or a plurality of devices on the micro-heater 10 at precise positions. During the device pick-up process, when the micro-heater 10 is pressed against the donor substrate and a vacuum is applied through the through-hole H, the device is fixed to the micro-heater 10 by the vacuum suction force. After bonding the device to the substrate, the vacuum may be released or a positive pressure may be applied to detach the micro-heater 10 from the device.

As illustrated in FIG. 5B, the through-hole H may be formed in various shapes such as a circle or a rectangle. A size and number of the through-holes H may be determined by considering a size, weight, vacuum suction force of the device, and the like. For example, the larger the device, the larger the size of the through-hole H or the greater the number of through-holes H may be to ensure sufficient vacuum suction force.

In one embodiment, both the adhesive material A and the through-hole H may be formed in the debossed structure 130. In this case, the device may be more stably fixed by simultaneously using the adhesive force of the adhesive material A and the vacuum suction force through the through-hole H. In another embodiment, only the adhesive material A may be disposed, or only the through-hole H may be formed in the debossed structure 130.

A position of the through-hole H is not limited to only within the debossed pattern. For example, the through-hole H may be formed at a center, an edge, or a plurality of positions in the debossed structure 130. When a plurality of through-holes H are formed, each through-hole H may be connected to a common vacuum supply line to receive vacuum simultaneously.

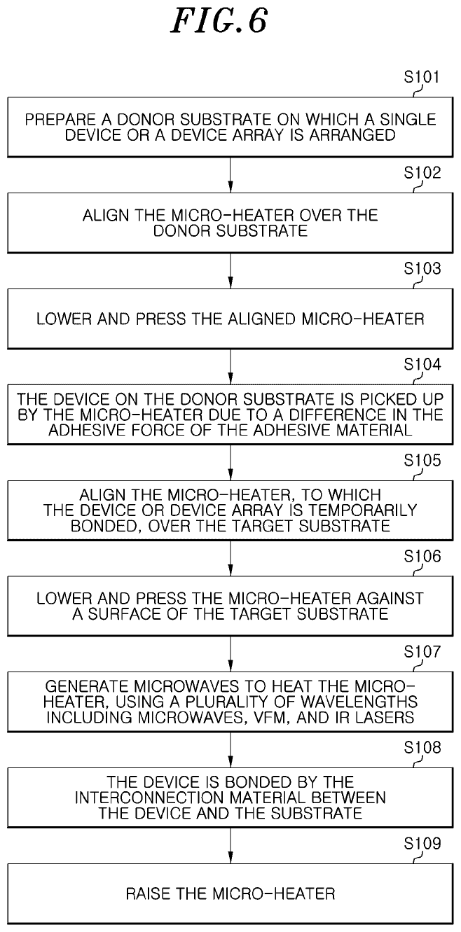

FIG. 6 is a flowchart for describing a device transfer and bonding method using a microwave-reactive micro-heater according to the embodiment of the present disclosure.

Referring to FIG. 6, the device transfer and bonding method according to the embodiment includes steps S101 to S109.

In step S101, a donor substrate on which a single device or a device array is arranged is prepared. The donor substrate refers to the substrate on which the devices to be transferred are placed, and may include a semiconductor wafer, a chip tray, or a dicing tape to which sawed chips are temporarily attached. The device may include a semiconductor device chiplet, an inorganic light-emitting diode, a micro light-emitting diode, and the like.

In step S102, the micro-heater is aligned over the donor substrate. The micro-heater refers to the microwave-reactive micro-heater described in FIGS. 1 to 5, and may pick up the device using an adhesive material disposed in a debossed structure or a vacuum suction force through a through-hole. The micro-heater and the device on the donor substrate are precisely aligned, so that each debossed structure of the micro-heater is disposed to correspond to a position of each device.

In step S103, the aligned micro-heater is lowered and pressed. The micro-heater is lowered toward the donor substrate, and the debossed structure of the micro-heater comes into contact with the device. At this time, a constant pressure may be applied so that the adhesive material and the device are in close contact, or a vacuum may be applied through the through-hole.

In step S104, the device on the donor substrate is picked up by the micro-heater due to a difference in the adhesive force of the adhesive material. When the adhesive force between the adhesive material of the micro-heater and the device is greater than the adhesive force between the donor substrate and the device, the device is attached to the micro-heater and separated from the donor substrate when the micro-heater is raised. Alternatively, when a vacuum is applied through the through-hole, the device may be fixed to the micro-heater by the vacuum suction force and picked up.

In step S105, the micro-heater, to which the device or device array is temporarily bonded, is aligned over the target substrate. The device picked up by the micro-heater moves to the target substrate, and the micro-heater and the target substrate are precisely aligned so that an electrode of the device and an electrode of the substrate correspond. The target substrate may include a printed circuit board (PCB), a semiconductor package substrate, a display substrate, and the like.

In step S106, the micro-heater is lowered and pressed against a surface of the target substrate. The micro-heater is lowered toward the target substrate, and the electrode of the device and the electrode of the substrate come into contact. At this time, a constant pressure is applied so that an interconnection material disposed between the electrode of the device and the electrode of the substrate comes into close contact.

In step S107, microwaves are generated to heat the micro-heater. The microwaves are absorbed by a microwave-reactive material constituting the micro-heater and converted into heat, and this heat is transferred to the interconnection material disposed between the electrode of the device and the electrode of the substrate. In addition to microwaves, a plurality of wavelengths may be used, including variable frequency microwaves (VFM) and infrared (IR) lasers. By using a combination of these electromagnetic waves, a heating rate, a maximum temperature, and a temperature distribution of the heater may be precisely controlled.

In step S108, the device is bonded by the interconnection material between the device and the substrate. The interconnection material is melted or cured by the heat transferred from the micro-heater to electrically and mechanically bond the electrode of the device to the electrode of the substrate. The interconnection material may include Tin (Sn)-based solder such as Tin (Sn) or Tin-Silver (SnAg) SAC305, alloy solder such as Tin-Bismuth (SnBi) or Tin-Indium-Bismuth (SnInBi), Gold-based solder such as Gold-Tin (AuSn), or Indium (In)-based solder such as Indium (In), or may be a combination of a plurality thereof, and may include Anisotropic Conductive Paste or Anisotropic Conductive Film.

In step S109, the micro-heater is raised. After the device is bonded to the substrate, the micro-heater is detached from the device by reducing the adhesive force of the adhesive material or releasing the vacuum through the through-hole. When the micro-heater is raised, the device remains bonded to the substrate, and the micro-heater may move back over the donor substrate to transfer and bond the next device.

The device transfer and bonding method according to the embodiment is characterized in that a plurality of devices may be simultaneously and precisely transferred and bonded using the microwave-reactive micro-heater described in FIGS. 1 to 5. By uniformly heating the heater using microwaves, uniformity of bonding quality is ensured, and the time and energy required for the bonding process may be reduced.

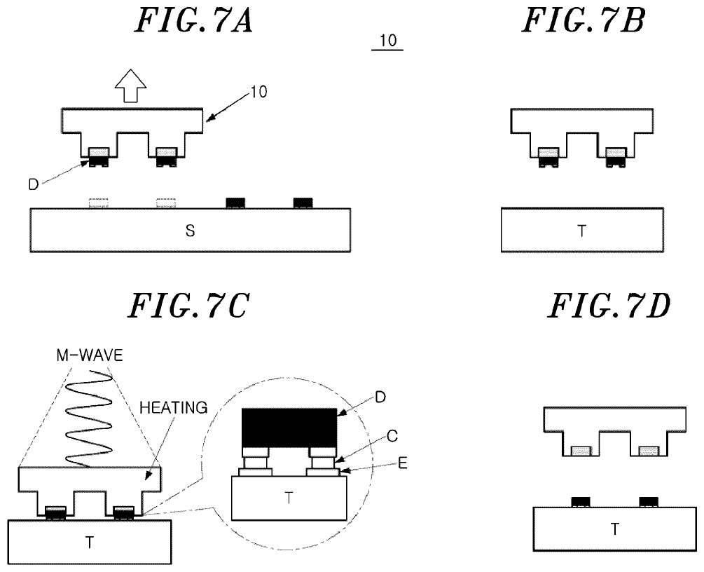

FIG. 7 is an exemplary view showing a device transfer and bonding method using a microwave-reactive micro-heater according to the embodiment of the present disclosure, sequentially.

FIG. 7A illustrates a pick-up process, FIG. 7B illustrates an alignment process, FIG. 7C illustrates a pressing and microwave generation (bonding) process, and FIG. 7D illustrates a heater detachment (bonding completion) process, respectively.

As illustrated in FIG. 7A, in the device pick-up process, the microwave-reactive micro-heater 10 is aligned over a donor substrate S, and the micro-heater 10 is lowered to contact the device D placed on the donor substrate S. The device D is fixed to the micro-heater 10 by the adhesive force of an adhesive material A disposed in a debossed structure 130 of the micro-heater 10 or by a vacuum suction force through a through-hole H, and when the micro-heater 10 is raised, the device D is picked up from the donor substrate S. FIG. 7A illustrates a plurality of devices D being picked up simultaneously.

As illustrated in FIG. 7B, in the device-substrate alignment process, the micro-heater 10 with the picked-up device is moved over a target substrate T and aligned. A position is adjusted so that an electrode of the device D fixed to the micro-heater 10 and an electrode E of the target substrate T correspond precisely. This alignment process may be performed with a precision at the micrometer level using an optical structure, a vision structure, or other alignment devices.

As illustrated in FIG. 7C, in the pressing and microwave generation (bonding) process, the micro-heater 10 is lowered to press the device D against the target substrate T. At this time, an interconnection material C is disposed between the electrode of the device D and the electrode E of the substrate T, and microwaves are generated to heat the micro-heater 10. FIG. 7C illustrates that microwaves (μ-wave) are irradiated from above, and a microwave-reactive material (μ-wave reactor) disposed inside the micro-heater 10 absorbs the microwaves to generate heat. The generated heat is transferred to the device D, and melts or cures the interconnection material C between the device D and the substrate T to complete electrical and mechanical bonding. The interconnection material C may include solder, anisotropic conductive paste, anisotropic conductive film, and the like. During the pressing process, a constant pressure is maintained so that the interconnection material C is uniformly distributed between the electrode of the device D and the electrode E of the substrate T and bubbles may be removed.

As illustrated in FIG. 7D, in the heater detachment (bonding completion) process, after the bonding is completed, the micro-heater 10 is raised and detached from the device D. The micro-heater 10 may be easily detached from the device D by reducing the adhesive force of the adhesive material A or releasing the vacuum through the through-hole H. The device D remains firmly bonded to the target substrate T, and the micro-heater 10 may be reused to transfer and bond the next device D.

The transfer and bonding method according to the embodiment visually represents the flowchart described in FIG. 6, and has an advantage of being able to process a plurality of devices simultaneously, thereby reducing process time.

FIG. 8 is an exemplary view showing a device transfer and bonding method using electromagnetic waves according to another embodiment of the present disclosure.

Referring to FIG. 8, the device transfer and bonding method according to the embodiment is characterized by using electromagnetic waves instead of microwaves in the pressing and microwave generation (bonding) process shown in FIG. 7C.

As illustrated in FIG. 8, the electromagnetic wave may be a laser. An electromagnetic wave generation device irradiates the micro-heater 10 with a laser, and the micro-heater 10 absorbs the laser to generate heat. Since a laser provides focused light energy of a specific wavelength, more localized and precise heating may be possible compared to microwaves.

The electromagnetic wave may include an infrared laser. The infrared laser is an electromagnetic wave with a wavelength in the range of 700 nm to 1 mm, which may be effectively absorbed by many materials and converted into heat. In one embodiment, the laser may be a surface-emitting laser. The surface-emitting laser may uniformly irradiate a large area, making it suitable for simultaneously heating a plurality of devices.

When using electromagnetic waves, a heating rate and a maximum temperature may be precisely controlled. For example, by adjusting an output, an irradiation time, a pulse pattern, etc., of the laser, heating conditions suitable for a type and characteristics of the interconnection material C may be implemented. Furthermore, the laser has a higher energy concentration than microwaves, which may shorten the heating time.

The embodiment may be performed in the same way as the method shown in FIG. 7, except for using electromagnetic waves instead of microwaves. That is, it proceeds in the order of device pick-up, device-substrate alignment, pressing and electromagnetic wave generation (bonding), and heater detachment.

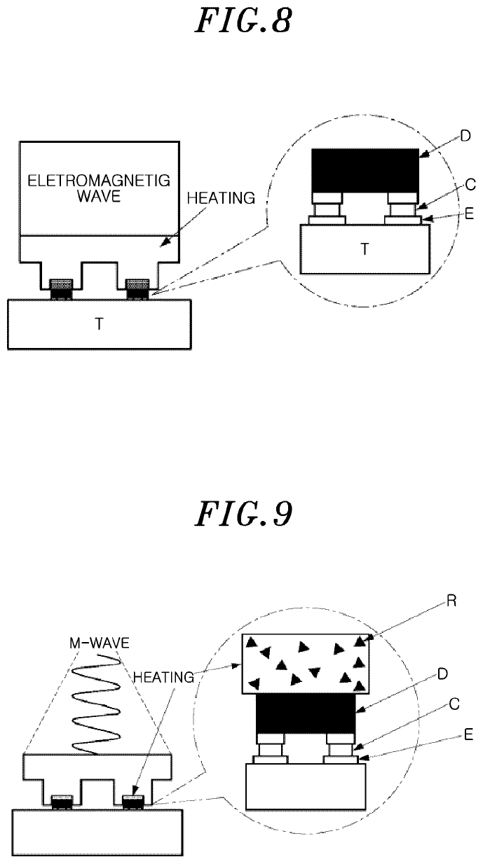

FIG. 9 is an exemplary view showing a device transfer and bonding method using a micro-heater in which a microwave-reactive material is partially disposed according to yet another embodiment of the present disclosure.

Referring to FIG. 9, the micro-heater 10 according to the embodiment partially includes a microwave-reactive material R. As illustrated in FIG. 9, the microwave-reactive material R is disposed only in a specific region of the micro-heater 10, and only this region may be heated in response to microwaves.

By composing only a part of the micro-heater 10 with the microwave-reactive material R and the remaining region with a microwave-non-reactive material, only a specific region may be selectively heated. For example, by composing only the region directly contacting the device D with the microwave-reactive material R and the remaining region with an insulating material, unnecessary heat loss may be reduced and energy efficiency may be improved.

In one embodiment, as illustrated in FIG. 9, the microwave-reactive material R may be disposed only in an upper region of the micro-heater 10. In this case, when microwaves are irradiated, only the upper region is heated, and a lower region may maintain a relatively low temperature. Such a structure may be useful for minimizing thermal deformation of an adhesive material A or for selectively heating only a specific part of the heater 10.

In another embodiment, the microwave-reactive material R may be disposed only around the debossed structure 130 where the device D is placed. In this case, only the area around the device D is intensively heated to effectively melt or cure the interconnection material C.

A temperature distribution of the heater 10 may be precisely controlled by adjusting a placement position, shape, concentration, etc., of the microwave-reactive material R. For example, a region with a high concentration of the microwave-reactive material R may be heated faster, and a region with a low concentration may be heated relatively slowly.

The embodiment may be performed in the same way as the methods shown in FIGS. 7 and 8, except for using a micro-heater 10 in which the microwave-reactive material R is partially disposed.

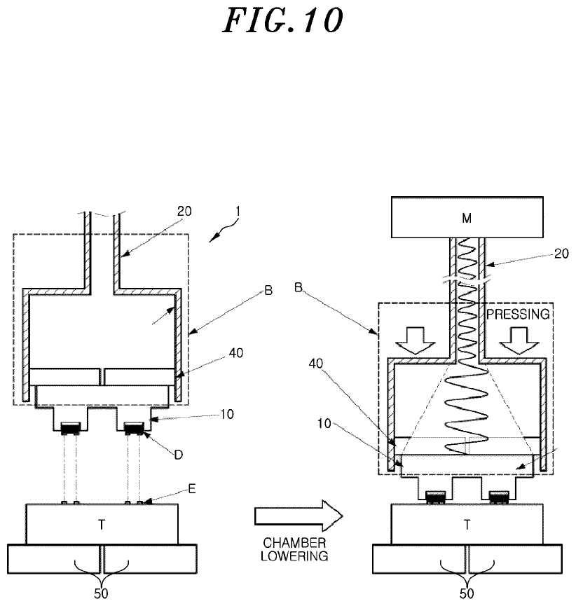

FIG. 10 is an exemplary view illustrating a schematic structure of a transfer and bonding apparatus 1 using a microwave-reactive micro-heater 10 according to an embodiment of the present disclosure.

Referring to FIG. 10, the transfer and bonding apparatus 1 according to the embodiment includes a microwave generator M, a waveguide 20, a chamber 30, a micro-heater fixing structure 40, and a stage 50.

The microwave generator M generates microwaves. The microwave generator M may include a magnetron, a high-frequency oscillator, and the like, and may control a frequency, output, irradiation time, etc., of the microwaves.

The waveguide 20 guides the microwaves generated by the microwave generator M and transmits them to the chamber 30. The waveguide 20 is fabricated from a material reflecting microwaves to minimize the loss of microwaves, and has a structure allowing microwaves to propagate efficiently inside. A cross-section of the waveguide 20 may be a rectangle, a circle, or various other shapes.

The chamber 30 confines the microwaves, allowing the microwaves to react with the micro-heater 10. The material of the chamber 30 may be fabricated from a material reflecting microwaves, and may be a metallic material. The size of the chamber 30 may vary from the size of the micro-heater 10 to the size of the target substrate T. The chamber 30 may have a specific structure and shape to allow microwaves to be uniformly distributed inside. The structure of the chamber 30 is not limited to a rectangular shape, and may be various shapes including a hemispherical, pyramidal, or inverted pyramidal shape.

The micro-heater fixing structure 40 functions to fix the micro-heater 10 and apply pressure. The micro-heater 10 may be fixed by applying a vacuum through a hole formed in the micro-heater fixing structure 40. This structure may be composed of a material not reacting with microwaves. The material not reacting with microwaves may include organic materials such as quartz, glass, Teflon, plastic, ceramic, intrinsic silicon (undoped), silicone, and siloxane.

The stage 50 functions to hold the donor substrate S or the target substrate T for bonding. The substrate T may be fixed by a vacuum hole formed in the stage 50. Furthermore, it may function to align the micro-heater 10 with the device D by moving the substrate in the X-Y-Z directions and rotational direction, or to align the picked-up device with an electrode E of the substrate T. Furthermore, by moving in the Z direction, it may pick up the device D with the micro-heater 10, apply pressure to the device D picked up by the micro-heater 10, or detach the device D from the micro-heater 10.

As illustrated on the left side of FIG. 10, the transfer and bonding apparatus 1 has a structure in which the micro-heater 10 is located at the top and the target substrate T is placed on the stage 50. The chamber 30 is included in a bonding head unit B and may move up and down together with the micro-heater fixing structure 40. The bonding head unit B may function to align the micro-heater 10 with the device D by moving in the X-Y-Z directions and rotational direction, or to align the picked-up device with the electrode E of the substrate T.

As illustrated on the right side of FIG. 10, during the pressing process, the micro-heater 10 is lowered to press the device D against the target substrate T, and at the same time, microwaves are transmitted to the chamber 30 through the waveguide 20 to heat the micro-heater 10. Inside the chamber 30, the microwaves are reflected and uniformly irradiated onto the micro-heater 10, and the micro-heater fixing structure 40 of the micro-heater 10 absorbs the microwaves to generate heat.

The transfer and bonding apparatus 1 according to the embodiment is an apparatus for implementing the transfer and bonding method described in FIGS. 6 and 7, and may simultaneously and precisely transfer and bond a plurality of devices D.

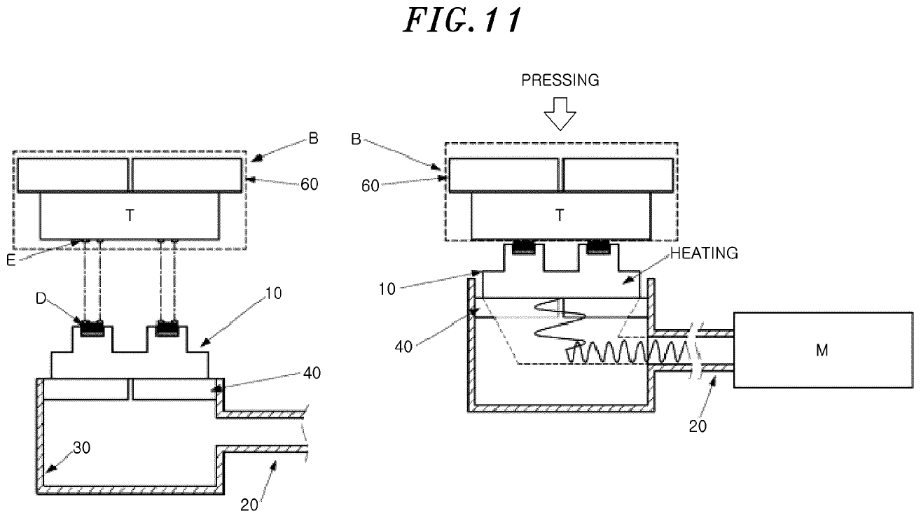

FIG. 11 is an exemplary view illustrating a schematic structure of a transfer and bonding apparatus using a microwave-reactive micro-heater 10 according to another embodiment of the present disclosure.

Referring to FIG. 11, the transfer and bonding apparatus according to the embodiment is similar to the transfer and bonding apparatus 1 shown in FIG. 10, but is characterized by a different position of the micro-heater 10 and a different direction of microwave irradiation.

As illustrated on the left side of FIG. 11, the transfer and bonding apparatus according to the embodiment has a structure in which the micro-heater 10 is located at the bottom and a target substrate T is fixed to a bonding head unit B at the top. A microwave generator M, a waveguide 20, and a chamber 30 are disposed below the stage 50, and microwaves are irradiated from the bottom upwards.

In the embodiment, the micro-heater 10 is disposed on the stage 50, and the stage 50 may be composed of a material not reacting with microwaves. For example, the stage 50 may be fabricated from a material such as quartz or ceramic, so that microwaves may pass through the stage 50 to reach the micro-heater 10.

As illustrated on the right side of FIG. 11, during the pressing process, the bonding head unit B is lowered to press the target substrate T against the device D picked up by the micro-heater 10, and at the same time, microwaves are transmitted from the lower waveguide 20 to the chamber 30 to heat the micro-heater 10. The microwaves pass through the stage 50 and are irradiated onto the micro-heater 10, and the micro-heater 10 absorbs the microwaves to generate heat.

The transfer and bonding apparatus 1 according to the embodiment performs the same function as the transfer and bonding apparatus 1 shown in FIG. 10, except that the micro-heater is located at the bottom and the microwaves are irradiated from the bottom. The position of the micro-heater 10 and the direction of microwave irradiation are not limited to the top or bottom, and may be variously designed according to the structure of the apparatus and process characteristics.

In one embodiment, a chamber 30 may also be disposed on the target substrate T side, so that two chambers 30 and waveguides 20 are disposed at the top and bottom. In this case, both the micro-heater 10 and the substrate T may be heated by irradiating microwaves from the top and bottom simultaneously. When both the micro-heater 10 and the substrate T are heated, the microwave energy used for heating may be reduced.

The structure of the transfer and bonding apparatus 1 according to the embodiment may be changed accordingly when using another light source instead of a microwave generator M. In one embodiment, when the light source is a laser, the waveguide 20 may be an optical fiber. The chamber 30 may be an optical structure including a plurality of lenses. In this case, the laser may be transmitted through the optical fiber and focused through the lenses to be irradiated onto the micro-heater 10.

In another embodiment, a laser compression bonding method may be applied. In this case, a laser beam generated from a laser generator may be converted into a uniform area light source by passing through a homogenizer.

The converted area light source passes through an optical structure transmitting the area light source having passed through the homogenizer, the optical structure being composed of at least one of Quartz, Glass, and Sapphire. In such a structure, instead of heating the entire micro-heater, the laser light is locally absorbed only by the device or a plurality of devices, allowing for selective heating.

When the device is heated, an interconnection material between the device and the substrate is melted or cured, thereby bonding the device to the substrate. This laser compression bonding method has advantages of high energy efficiency, minimizing thermal damage to the device, and enabling precise temperature control.

As described above, the present embodiment enables precise heat transfer to a desired region by using a micro-heater fabricated from a material that reacts to microwaves or electromagnetic waves. Furthermore, this embodiment enables a device to be precisely fixed and transferred using an adhesive material or a through-hole formed in a debossed structure of a micro-heater formed with an embossed and debossed structure. Furthermore, this embodiment enables a reduction in manufacturing process time and energy for electronic devices by allowing a plurality of electronic devices to be bonded to a target substrate at once. Furthermore, this embodiment enables ensuring uniformity of bonding quality and improving reliability of the device by uniformly heating a heater using microwaves or electromagnetic waves.

Implementations described herein may be embodied, for example, as a method or process, an apparatus, a software program, a data stream, or a signal. Even if discussed only in the context of a single form of implementation (e.g., discussed only as a method), the implementation of the features discussed may also be embodied in other forms (e.g., an apparatus or a program). An apparatus may be implemented with appropriate hardware, software, and firmware, etc. A method may be implemented in an apparatus such as a processor, which generally refers to a processing device including, for example, a computer, a microprocessor, an integrated circuit, or a programmable logic device, etc. A processor also includes a communication device such as a computer, a cell phone, a portable/personal digital assistant (“PDA”), and another device that facilitates communication of information between end-users.

Although the present disclosure has been described above with reference to limited embodiments and drawings, the present disclosure is not limited thereto. It will be apparent to those skilled in the art to which the present disclosure pertains that various modifications and variations may be made without departing from the technical spirit of the present disclosure and within the scope of equivalents of the claims set forth below.

What is claimed is:

1. A microwave-reactive micro-heater, fabricated from a material for generating heat in response to microwaves or electromagnetic waves, the microwave-reactive micro-heater comprising:
an embossed structure formed on an upper surface of a planar substrate;
a debossed structure formed within the embossed structure; and
at least one of an adhesive material for temporarily fixing a device in the debossed structure and a through-hole for applying a vacuum.

2. The microwave-reactive micro-heater of claim 1, wherein the material generating heat in response to the microwaves or the electromagnetic waves includes at least one selected from a group essentially consisting of silicon, ferrite, silicon carbide (SiC), zirconia, carbon nanotube, graphite, activated carbon, iron oxide, nickel, alumina, and conductive polymer.

3. The microwave-reactive micro-heater of claim 1, wherein the embossed structure has a shape of one of a rectangle, a circle, a triangle, and a cross, and the debossed structure has a shape the same as or different from the embossed structure.

4. The microwave-reactive micro-heater of claim 1, wherein the adhesive material includes at least one selected from a group essentially consisting of rubber, acrylic adhesives, silicone adhesives, epoxy adhesives, polyimide adhesives, polyurethane adhesives, polyvinyl acetate (PVA), pressure-sensitive adhesives, and cyanoacrylate.

5. The microwave-reactive micro-heater of claim 1, wherein the adhesive material has a microwave-reactive material dispersed therein and generates heat in response to the microwaves or the electromagnetic waves.

6. The microwave-reactive micro-heater of claim 1, wherein the microwave-reactive micro-heater absorbs at least one electromagnetic wave including at least one among microwaves, infrared, visible light, ultraviolet, and X-rays and converts the electromagnetic wave into heat.

7. The microwave-reactive micro-heater of claim 1, wherein the electromagnetic waves include a variable frequency microwave having a frequency changing continuously over a time axis.

8. The microwave-reactive micro-heater of claim 6, wherein the electromagnetic waves include a laser.

9. The microwave-reactive micro-heater of claim 1, wherein the microwave-reactive micro-heater is fabricated from a silicon wafer, and
wherein a doping concentration of the silicon wafer is adjusted to control an efficiency of reacting to microwaves.

10. The microwave-reactive micro-heater of claim 1, including one or more embossed structures and one or more debossed structures,
wherein the one or more embossed structures are formed on the upper surface of the planar substrate, and the one or more debossed structures are respectively formed within the one or more embossed structures, and
wherein the microwave-reactive micro-heater includes an array of the embossed structure, the debossed structure, the one or more embossed structures and the one or more debossed structures arranged to simultaneously fix and transfer a plurality of devices at precise positions.

11. A device transfer and bonding method comprising:
preparing a donor substrate on which a single device or a device array is arranged;
aligning a microwave-reactive micro-heater over the donor substrate;
lowering and pressing the aligned microwave-reactive micro-heater;
picking up the device from the donor substrate to the microwave-reactive micro-heater by an adhesive force of an adhesive material or a vacuum suction force through a through-hole;
aligning the microwave-reactive micro-heater, to which the device is temporarily bonded, over a target substrate;
lowering and pressing the microwave-reactive micro-heater against a surface of the target substrate;
generating microwaves or electromagnetic waves to heat the microwave-reactive micro-heater;
bonding the device by an interconnection material between the device and the target substrate; and
raising the microwave-reactive micro-heater to detach the microwave-reactive micro-heater from the device.

12. The device transfer and bonding method of claim 11, wherein the heating of the microwave-reactive micro-heater by generating microwaves or electromagnetic waves uses a combination of a plurality of wavelengths including at least one selected from the group consisting of the microwaves, variable frequency microwaves, and infrared lasers.

13. The device transfer and bonding method of claim 11, wherein the interconnection material includes at least one selected from the group consisting of a tin (Sn)-based solder, a tin-bismuth (SnBi) alloy solder, a tin-indium-bismuth (SnInBi) alloy solder, a gold-tin (AuSn)-based solder, an indium (In)-based solder, an anisotropic conductive paste (ACP), and an anisotropic conductive film (ACF).

14. The device transfer and bonding method of claim 11, wherein the microwave-reactive micro-heater includes a plurality of embossed and debossed structures, and simultaneously picks up a plurality of devices to simultaneously bond the plurality of devices to the target substrate.

15. The device transfer and bonding method of claim 11, wherein the detaching of the microwave-reactive micro-heater from the device includes reducing an adhesive force of the adhesive material or releasing a vacuum through the through-hole.

16. A device transfer and bonding apparatus comprising:
a microwave-reactive micro-heater generating heat in response to microwaves or electromagnetic waves;
a microwave generator generating the microwaves or the electromagnetic waves;
a waveguide guiding the microwaves or the electromagnetic waves;
a chamber confining the microwaves or the electromagnetic waves;
a micro-heater fixing structure fixing the microwave-reactive micro-heater and applying pressure; and
a stage fixing a donor substrate or a target substrate,
wherein the micro-heater fixing structure and the stage are operable to move in x-y-z directions and a rotational direction to align the microwave-reactive micro-heater with a device.

17. The device transfer and bonding apparatus of claim 16, wherein the chamber is fabricated from a material reflecting the microwaves or the electromagnetic waves, and includes a metallic material.

18. The device transfer and bonding apparatus of claim 16, wherein the micro-heater fixing structure is composed of a material not reacting with the microwaves or the electromagnetic waves, and the material includes at least one selected from the group consisting of quartz, glass, Teflon, plastic, ceramic, intrinsic silicon, silicone, and siloxane.

19. The device transfer and bonding apparatus of claim 16, wherein the chamber is disposed at an upper portion and a lower portion of the microwave-reactive micro-heater, respectively, and irradiates the microwaves or the electromagnetic waves simultaneously from the upper portion and the lower portion of the microwave-reactive micro-heater.

20. The device transfer and bonding apparatus of claim 16, wherein the microwave generator is a laser generator, and includes:
a homogenizer converting a laser beam generated from the laser generator into a uniform area light source; and
an optical structure transmitting the area light source having passed through the homogenizer, the optical structure being composed of at least one of quartz, glass, and sapphire,
wherein the area light source passes through the optical structure and is locally absorbed by a device or a plurality of devices to selectively heat the device, and melts and cures an interconnection material between the device and a substrate to bond the device to the substrate.
